(19) United States
(12) Patent Application Publication
(10) Pub. No.: US 2024/0161645 A1
(43) Pub. Date: May 16, 2024

(54) DIGITAL COMPANION FOR PERCEPTUALLY ENABLED TASK GUIDANCE

(71) Applicant: Siemens Aktiengesellschaft, Munich (DE)

(72) Inventors: Dan Yu, Orinda, CA (US); Mareike Kritzler, San Francisco, CA (US); John Hodges, Jr., Moss Beach, CA (US)

(73) Assignee: Siemens Aktiengesellschaft, Munich (DE)

(21) Appl. No.: 18/550,339

(22) PCT Filed: Mar. 31, 2022
(86) PCT No.: PCT/US2022/022714

§ 371 Date: Sep. 13, 2023

Related U.S. Application Data
(60) Provisional application No. 61/168,426, filed on Apr. 10, 2009.

(51) Int. Cl. G09B 5/06; G06F 9/451; G06F 30/20; G06T 19/00; G06V 10/764; G06V 10/82

(52) U.S. Cl. CPC G09B 5/06; G06F 9/453; G06F 30/20; G06T 19/006; G06V 10/764; G06V 10/82

(57) ABSTRACT

A method for a digital companion includes receiving information representing human knowledge and converting the information into computer-readable form. A digital twin of a scene is created and environmental information from the scene is received and evaluated to detect errors in performance of the process. Guidance is provided to a user based on the detected error. A system for providing a digital companion the system includes a computer processor in communication with a memory storing instructions that cause the computer processor to instantiate a knowledge transfer module receiving human knowledge and converting the information into machine-readable form, create a process model representative of a process performed using the human knowledge, a perception grounding module identifying entities and their status, a perception attention module evaluating the digital twin to detect an error during the step-based process, and a user engagement module communicating a detected error to a user and show the right next step.

### TECHNICAL FIELD

This application relates to industrial manufacturing.

### BACKGROUND

Human workers are needed in many settings. Consider an industrial setting where they assemble work pieces, perform maintenance routines, or execute other manual tasks. Many of these tasks require prior knowledge of the task execution as well as a precise step by step procedure for execution. However, situations arise where a worker may not have the exact skill level for a particular task although it is required that the worker perform the task step by step. Additionally, manual task execution is prone to errors even if a worker might have a high/exact skill level.

Machine Learning systems may help with simulation perception and prediction, while knowledge-based systems may help with prediction, simulation, and explanation, but thus far these approaches have not been integrated. Conventionally, the training of human workers is supported through written documentation and paper-based training material, computer programs, and the personal advice and guidance of experienced peers and supervisors who are rare and not always readily available.

In view of the above challenges improved methods and systems are desired which enable non-expert workers to competently perform complex tasks and may detect and correct errors during task execution where even skilled workers might make mistakes.

### SUMMARY

A computer-implemented method for a digital companion includes in a computer processor, receiving information representative of human knowledge, then converting the received information into a computer-readable form including at least one task-based process to be performed. A digital twin of a scene for performing the task-based process is created from a predefined process model. Then environmental information from a real-world scene for performing the task-based process is received. The newly received information is evaluated to detect an error in the performance of the task-based process based on the captured human knowledge learned by the system, and guidance is provided to a user.

According to embodiments, the method may further include converting the received information representative of human knowledge into a predefined process model, which in some embodiments may be represented by a knowledge graph. Models relating to the system may include a process model representative of execution of the task-based process, a scene model representative of the real-world scene for performing the task-based process, and a user model representative of a worker performing tasks in the task-based process. The method includes the scene model embodied as a digital twin of the real-world scene for performing the task-based process. The digital twin may be updated periodically or in response to events based on the received environmental information. The environmental information from the real-world scene contains data generated from one or more sensors located in the real-world scene. Other physiological sensors may be associated with a user and provide additional environmental information relating to the user. Guidance to the user may be provided in a head-mounted display using augmented reality, on a display visible or sensed by the user, or any suitable human-machine interface, e.g. speech conversation or natural language text. The method may receive information regarding the user and customize the guidance provided to the user based on the user information. Information regarding the user may be obtained from a login of the user to the system or from a physiological sensor associated with the user. In some embodiments, each step in the task-based process is stored in a knowledge graph. Each step may be linked to at least one entity required to execute the step. At each step, information relating to pre-dependencies for performing the task are stored along with the task. Captured sensory data from the scene may provide information from the scene and a neural network may be used to classify entity objects in the captured data. Each classified entity object is associated with a unique identifier identifying the entity object based on a semantic model of the system.

According to a system for providing a digital companion the system includes a computer processor in communication with a non-transitory memory, the non-transitory memory storing instructions that when executed by the computer processor cause the processor to instantiate a knowledge transfer module for receiving information representative of human knowledge and convert the information into a machine-readable form, create a knowledge base comprising a process model representative of a step-based process performed using the human knowledge, create a perception grounding module that identifies entities in a physical world and builds a digital twin of the physical world; create a perception attention module for evaluating the digital twin of the physical world to detect an error in execution of the step-based process, and create a user engagement module for communication of a detected error to a user operating in the physical world. The knowledge base includes a process model representative of the step-based process, a scene model representative of the physical world, and a user model representative of the user. The system further includes a display device to communicate the detected error to the user.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 is a block diagram of a digital companion according to aspects of embodiments described in this disclosure.

FIG. 2 is a block diagram of a knowledge transfer module of a digital companion according to aspects of embodiments described in this disclosure.

FIG. 3 is a block diagram of a perception grounding module of a digital companion according to aspects of embodiments described in this disclosure.

FIG. 4 is a block diagram of a perception attention module of a digital companion according to aspects of embodiments described in this disclosure.

FIG. 5 is a block diagram of a user engagement module of a digital companion according to aspects of embodiments described in this disclosure.

### DETAILED DESCRIPTION

As human workers complete tasks in an industrial environment, there are numerous procedures that must be followed to successfully perform that task. Knowledge required to understand and properly perform the task must be taught to the worker. In some cases, documentation may be referenced which provide instructions on performing the task. Other means, such as instructional videos, diagrams, paper-based documents, or recorded instructions may be used to transfer knowledge to the worker.

According to embodiments described herein, a digital companion is presented that receives information relating to a task and interprets an environment and a user's skill level to provide relevant and helpful information to a worker.

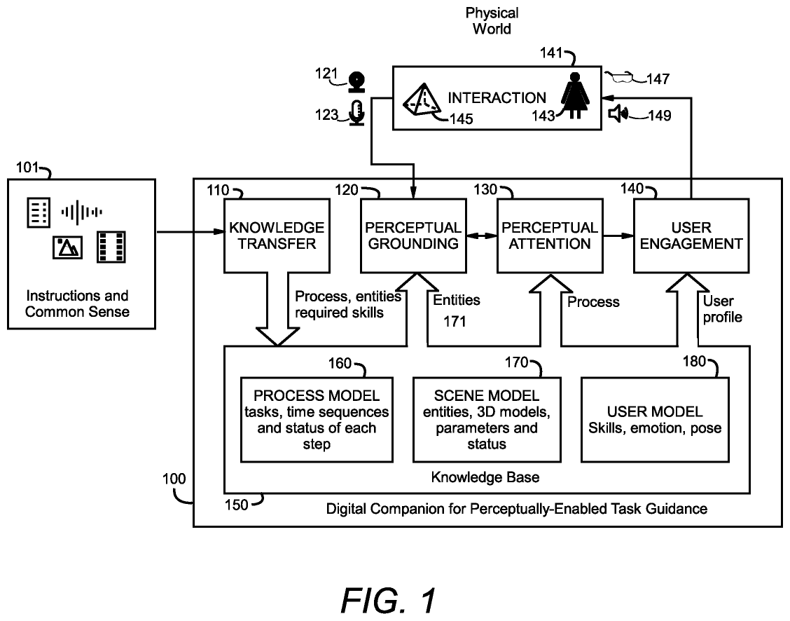

FIG. 1 is a block diagram of a digital companion according to embodiments of this disclosure. The digital companion 100 uses existing documentation representative of human knowledge 101. The documentation 101 is received at a knowledge transfer module 110. The knowledge transfer module converts the information contained in the documentation 101 into a format that is structured and easily processible by a computer. The converted information is incorporated into a knowledge base 150. The knowledge base includes information related to the task and environment including models that represent the process 160, the scene 170, and users 180.

The physical world 141 includes the worker 143 and the task-based process 145. The nature of states in the physical world 141 may be captured by various sensors including cameras 121, microphones 123, radioactivity sensors, hazardous chemical sensors or any other type of sensory intended to augment the sensory capabilities of a user to generate environmental information. Environmental information may include information relating to objects within the scene such as materials, workpieces, tools, machines, and the like. Additionally, environmental information includes people within the scene and their states and actions. For example, a user may be associated with a wearable device which monitors the user's heartrate. If the user is stressed or overexerting during the performance of a task, the monitor may report a rapid heart rate to the digital companion and the user may be instructed to slow down or stop the activity for the sake of safety. The sensed data is provided to a perception grounding module 120. The perception grounding module 120 takes inputs from the environment to recognize entities in the physical world 141 and identifies the status of each entity. The perception grounding module 120 utilizes neural network models, including the process model 160, scene model 170 and user model 180 to recognize objects in view. Additionally, the perception grounding module 120 may be configured to perform natural language processing (NLP) to recognize conversations or voice commands. Each entity identified in the scene will have an associated status which is verified by the perception grounding module 120. With the information acquired, the perception grounding module 120 will construct a digital twin of the scene.

The perception grounding module 120 provides the state of the scene to the perception attention module 130. The perception attention module 130 assesses the current state of the physical world scene and tracks the statuses of the most relevant entities. The procedure for the task is determined from the knowledge graph in the knowledge base 150 to determine the next steps in the process. The perception attention module 130 will make note of any entities that will be part of the next process step and conversely, if any detected entity will interfere with the performance of the next process step. This tracking includes notation of entities that are unrecognized, and entities that are new to the scene.

Exceptions to the normal progression of the process begin performed are reported back to the perception grounding module 120 allowing the perception grounding module 120 to allow the perception grounding module 120 to maintain the digital twin in real time. The perception attention module 130 will request updates of each entity from the perception grounding module 120 and monitor the scene for completion of the next step in the process.

Finally, the user engagement module 140 takes the next step in the task process and compares the requirements of that step with the required user skills and expertise in the knowledge graph. The user engagement module 140 may also be aware of a worker's state based on sensed data from system sensors 121, 123 or other sensors which measure physiological aspects of the user. In addition, the user may login to the system, thereby providing information as to the user's employment status, including skill levels and years of experience. When the user engagement module 140 detects a deviation from the current process step, the user may be provided with additional guidance based on the user model 180 in the knowledge base 150. The guidance may include instructions for reversing certain steps and reperforming the correct steps to complete the task. Additional guidance may be provided to the user 143 by verbal instructions via speaker 149 and/or by visual means using a head mounted display 147 configured for augmented reality (AR).

Each of the modules will now be described in greater detail.

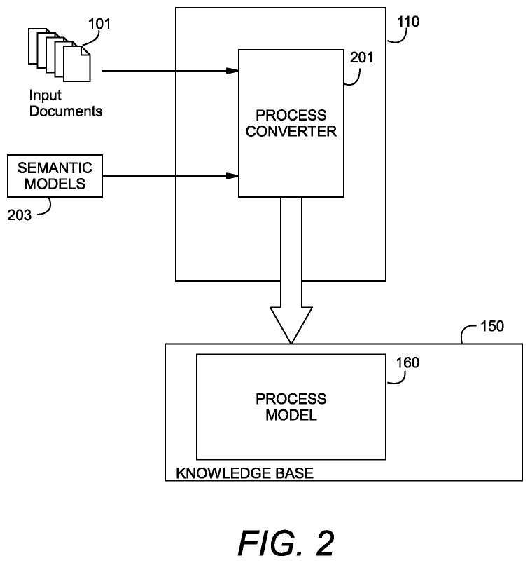

FIG. 2 is a block diagram of the knowledge transfer module 110. Human knowledge in the form of input documents 101 may include information residing in various formats. For example, input documentation 101 may be in the form of printed task lists, manuals, illustrated instructions, documented policies or instruction videos. This list provides some examples, but other formats may act as input documents 101.

The information contained in the input documents 101 is provided to the process converter 201, which converts the process information in the input documents 101 into a form which is capable for a machine to validate, understand and therefore execute on the converted process. The process converter 201 converts the process while aligning the converted process to domain-specific semantic models 203. The semantic models may contain common knowledge previously translated into computer readable format, or may be domain independent, such as quantities, units, dimensions, etc. The resulting converted procedure may be generated as knowledge graphs that are stored as process model 160 as part of the knowledge base 150.

The knowledge graphs will represent steps in the process and include additional information such as pre-dependencies, external dependencies, names, and unique IDs for related entities. The entities may include concepts such as tools, roles, work pieces and environmental aspects. The knowledge transfer module 110 serves as a builder for the knowledge base 150, which serves as the foundation of other modules in the architecture shown in FIG. 1. The semantic models 203 are representative of operation procedures as well as common sense knowledge regarding elements of the environment and their relationships. The resulting knowledge graphs contain all procedural steps and related entities linked together and aligned with common sense knowledge to enable an understanding of how the process may be performed.

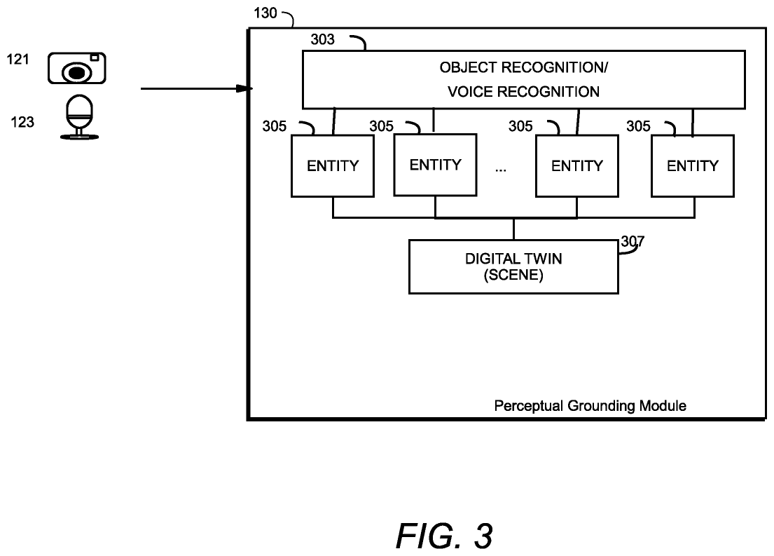

FIG. 3 is a block diagram of a perception grounding module 130 according to aspects of embodiment of this disclosure. Inputs to the perception grounding module 130 include multi-modal inputs from devices including but not limited to cameras 121, an RGBD or other camera technologies may be used, microphones 123, or other sensors placed in the environment. The perception grounding module 130 performs object recognition 303 and identifies each object's status. The perception grounding module 130 provides a holistic overview of the scene and the related entities in the scene along with their associated status. Sequences or order of status changes in time may also be stored by the perception grounding module 130.

The perception grounding module 130 may leverage neural network models to classify objects in the scene. Further speech recognition technologies 303 may be used to recognize conversations or voice commands. The perception grounding module 130 may use expected entities from semantic models of the system and compare them with detected entities 305 to enhance the object recognition 303 process. Each detected entity is marked with its corresponding status. Status information may include whether the object was expected, if the object is functioning as expected, and other information. The perception grounding module creates a digital twin 307 of the scene including spatial, physical, electrical or informational relationships (e.g., interconnection of a computer to the internet, cloud, or other network) to other entities as well as semantic relationships between the entities identified.

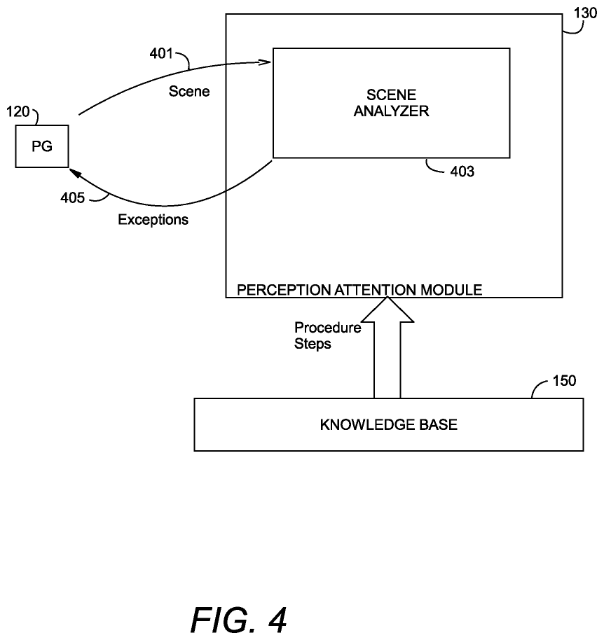

FIG. 4 is a block diagram of a perception attention module 130 according to aspects of embodiments in this disclosure. The perception attention module receives scene information 401 from the perception grounding module 120. The perception attention module 130 uses a scene analyzer 403 to assess a situation represented in the scene information 401. The perception attention module 130 tracks status changes for entities in the scene information 401, particularly noting status changes in the most relevant and salient entities with regard to the next process step received from the knowledge base 150. In particular, the scene analyzer 403 will track entities such as those entities that are unrecognized, unexpected, new to the scene, or spatially located such that their location could interfere with the performance of the next process step. The perception attention module 130 will also place special attention on entities that will be used in subsequent process steps.

The perception attention module 130 identifies any exceptions to the scene with respect to successful completion of the next process step. To assist the perception grounding module 120 in monitoring the scene in real time, the perception attention module 130 reports exceptions 405 back to the perception grounding module 120 and requests updates to the scene information 401 with respect to the entities associated with the exceptions 405.

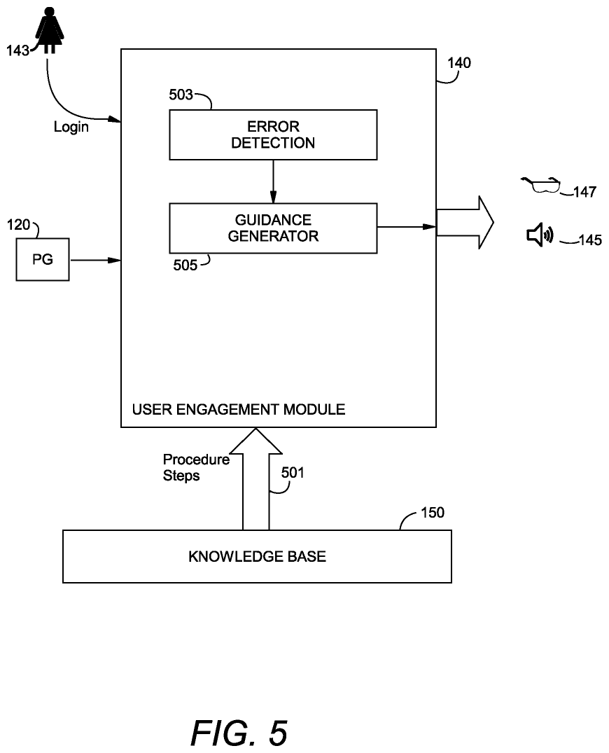

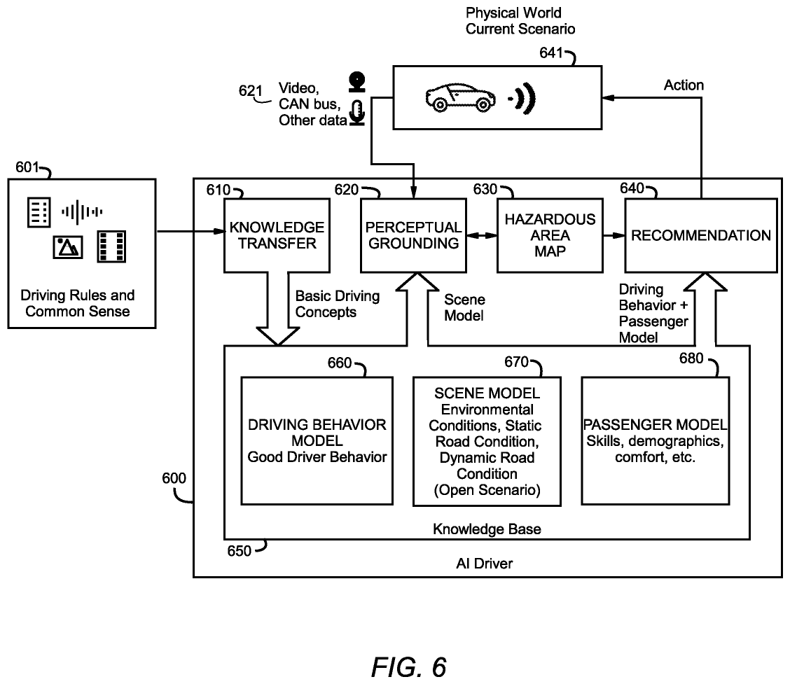

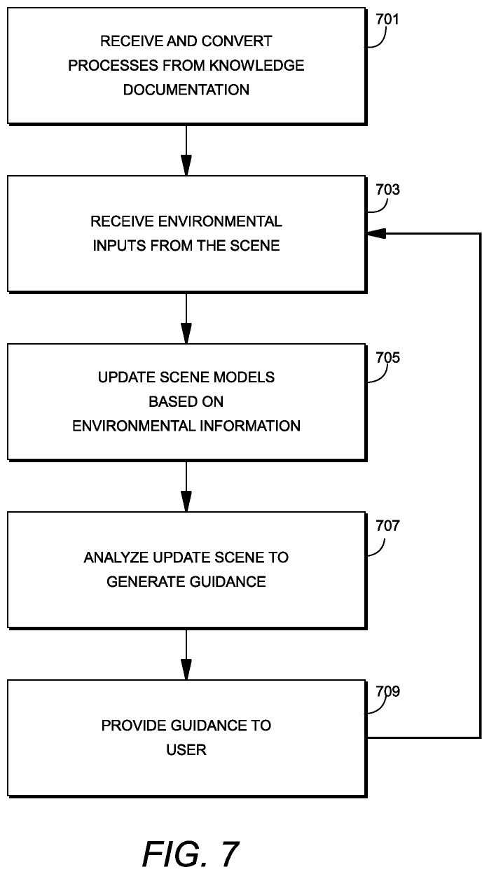

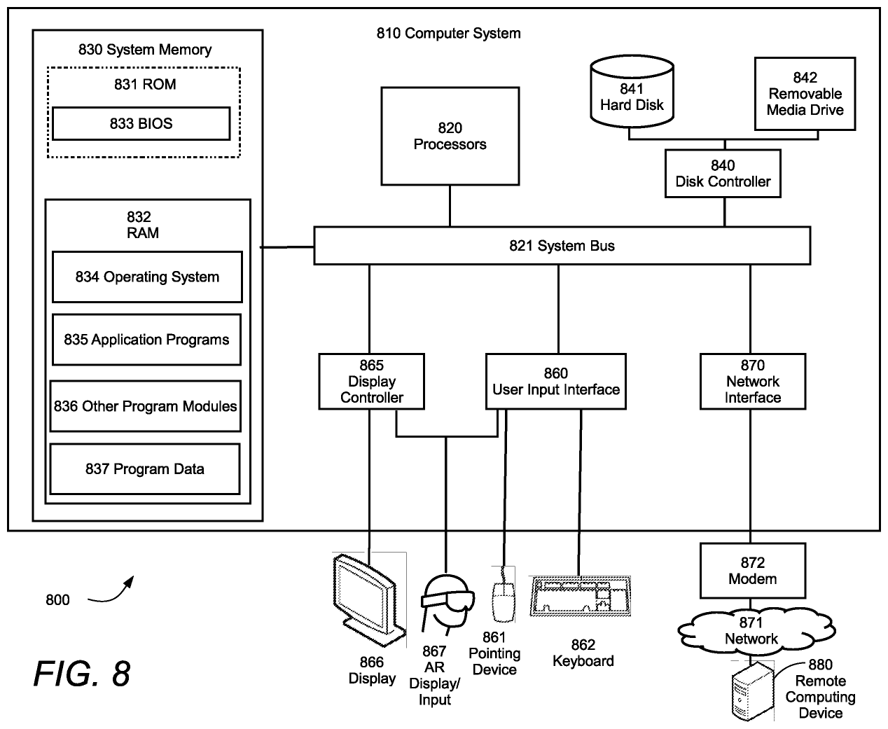

FIG. 5 is a user engagement module 140 according to aspects of embodiments of this disclosure. The user engagement module 140 takes the next step in the process 501 from the knowledge base 150 and compares the user skills and expertise needed for the next step with the information from the scene, including the scene information generated by the perception attention module 120. The user engagement module 140 may also receive information relating to a user and the state of the user. For example, the user's experience level and current level of attention or alertness may be ascertained from the user's login information and physiological sensors associated with the user. If a mistake is detected during execution of the current process step, the user engagement module 140 may provide additional guidance to the user. The additional guidance may be customized for the user based on the user's skill level. The user's skill level may be obtained through observation of the user's actions or from a user profile provided to the digital companion when the user 143 logs into the system.

The user engagement module 140 performs error detection on the process step currently being performed. When a mistake is detected, the user engagement module 140 generates guidance 505 customized to the current user 143. The user 143 may receive instructions instructing the user 143 to reverse steps and the re-perform the steps correctly. The user engagement module 140 will consider the user's safety when providing guidance to ensure that the user will be unharmed during the task execution. The user engagement module 140 may augment the user's scene perception through augmented reality (AR). The AR may include a dialog interface based on the user's skill level, expertise, and state. Other communication to the user may be utilized including audio guidance, or tactile signals may be used to communicate guidance to the user.

FIG. 6. provides a block diagram of a specific use case for the architecture of FIG. 1. FIG. 6 depicts the use of the digital companion architecture to instantiate an artificial intelligence driver 600. Inputs 601 include driving rules and common sense with respect to the task of driving a vehicle. The inputs 601 are converted to a machine-readable format by the knowledge transfer 610 for storage in the knowledge base 650. The knowledge base 650 comprises a driver behavior model 660, a scene model 670, and a passenger model 680. The driver behavior model 660 represents behavior that would generally be considered behaviors of a good driver. The scene model 670 describes the current scene including environmental conditions, static and dynamic road conditions to provide an overview of the current driving conditions. The passenger model 680 is representative of a passenger or operator of the vehicle and may consider information including, driver skills, ergonomics, and comfort status of the operator.

The perceptual grounding module 620 receives sensor data 621 from the physical world 641. These data may include captured video, data from a CAN bus or other data related to the vehicle via sensors installed in the vehicle. The perception grounding module 620 adapts the default scene model from the knowledge base 650 to match the current scene based on the sensor data 621. From the current scene model, potential hazards detected in the scene are identified and a hazardous area map 630 is generated. Based on the identified hazards and the profile of the operator, including driving behavior and a model representing the vehicle operator, a recommendation 640 is generated. The recommendation 640 may include warnings or guidance provided to the vehicle operator (or the autonomous vehicle) to enable the operator to take action to navigate hazards identified by the Al driver 600. In some embodiments, the vehicle may be controlled by the Al driver 600 itself, where the recommendation 680 generates actions in the form of control signals for operating the vehicle systems. Such systems may include acceleration, braking, steering or other vehicle operations. These embodiments may provide self-driving features to the vehicle.

The preceding example is provided by way of example only. Many other uses for the digital companion architecture in FIG. 1 may be contemplated within the scope of this disclosure. Any process and environment may provide input to a digital companion. The digital companion will model the process, the environment and the operators interacting with that environment to produce models of the current scene and to optimize execution of the process through guidance provided based on operations and common sense regarding the process being performed. Suggestions or actions may be customized for a particular user, based on a user profile including skill and experience levels, personal preferences, or other states of the user detectable by sensors associated with the user. Any type of sensor capable of providing information regarding the environmental factors or provide information about the state of the user may be included in the system to provide useful information to the digital companion. Useful information is information used by the digital companion in constructing models relating the process, scene or user or provides insight into the use of an existing model to provide improvements or enablement of a user to perform a desired task.

FIG. 7 is a process flow diagram for a computer-implemented method of providing a digital companion to a process according to aspects of embodiments described in this disclosure. Human knowledge in the form of documentation is received and converted to a machine-readable form 701. Documentation may include written instructions, designs, manuals, instructions, instructional videos, and the like. The conversion may take these input documents and convert them into a format such as a knowledge graph, which are stored in a knowledge base. Sensors located in the environment or scene produce values relating to the state of entities in the scene. These values are input as environmental inputs to the digital companion 703. Models of the scene stored in the knowledge base are updated based on the newly received environmental information 705. When the scene has been updated with the recently received environmental information, the new scene is analyzed with respect to the process being performed. Any errors or impediments to performing the next scheduled step in the process may be identified and corrective guidance may be generated 707. The generated guidance is provided to the user 709. The presentation to the user may be customized for a particular user. The customization may be based on a state of the user, including experience or skill level, current physical condition of the user (e.g., tired, inattentive, etc.)

FIG. 8 illustrates an exemplary computing environment 800 within which embodiments of the invention may be implemented. Computers and computing environments, such as computer system 810 and computing environment 800, are known to those of skill in the art and thus are described briefly here.

As shown in FIG. 8, the computer system 810 may include a communication mechanism such as a system bus 821 or other communication mechanism for communicating information within the computer system 810. The computer system 810 further includes one or more processors 820 coupled with the system bus 821 for processing the information.

The processors 820 may include one or more central processing units (CPUs), graphical processing units (GPUs), or any other processor known in the art. More generally, a processor as used herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting, or transmitting information for use by an executable procedure or an information device, and/or by routing the information to an output device. A processor may use or comprise the capabilities of a computer, controller, or microprocessor, for example, and be conditioned using executable instructions to perform special purpose functions not performed by a general-purpose computer. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

Continuing with reference to FIG. 8, the computer system 810 also includes a system memory 830 coupled to the system bus 821 for storing information and instructions to be executed by processors 820. The system memory 830 may include computer readable storage media in the form of volatile and/or nonvolatile memory, such as read only memory (ROM) 831 and/or random-access memory (RAM) 832. The RAM 832 may include other dynamic storage device(s) (e.g., dynamic RAM, static RAM, and synchronous DRAM). The ROM 831 may include other static storage device(s) (e.g., programmable ROM, erasable PROM, and electrically erasable PROM). In addition, the system memory 830 may be used for storing temporary variables or other intermediate information during the execution of instructions by the processors 820. A basic input/output system 833 (BIOS) containing the basic routines that help to transfer information between elements within computer system 810, such as during start-up, may be stored in the ROM 831. RAM 832 may contain data and/or program modules that are immediately accessible to and/or presently being operated on by the processors 820. System memory 830 may additionally include, for example, operating system 834, application programs 835, other program modules 836 and program data 837.

The computer system 810 also includes a disk controller 840 coupled to the system bus 821 to control one or more storage devices for storing information and instructions, such as a magnetic hard disk 841 and a removable media drive 842 (e.g., floppy disk drive, compact disc drive, tape drive, and/or solid-state drive). Storage devices may be added to the computer system 810 using an appropriate device interface (e.g., a small computer system interface (SCSI), integrated device electronics (IDE), Universal Serial Bus (USB), or FireWire).

The computer system 810 may also include a display controller 865 coupled to the system bus 821 to control a display or monitor 866, such as a cathode ray tube (CRT) or liquid crystal display (LCD), for displaying information to a computer user. The computer system includes an input interface 860 and one or more input devices, such as a keyboard 862 and a pointing device 861, for interacting with a computer user and providing information to the processors 820. The pointing device 861, for example, may be a mouse, a light pen, a trackball, or a pointing stick for communicating direction information and command selections to the processors 820 and for controlling cursor movement on the display 866. The display 866 may provide a touch screen interface which allows input to supplement or replace the communication of direction information and command selections by the pointing device 861. In some embodiments, an augmented reality device 867 that is wearable by a user, may provide input/output functionality allowing a user to interact with both a physical and virtual world. The augmented reality device 867 is in communication with the display controller 865 and the user input interface 860 allowing a user to interact with virtual items generated in the augmented reality device 867 by the display controller 865. The user may also provide gestures that are detected by the augmented reality device 867 and transmitted to the user input interface 860 as input signals.

The computer system 810 may perform a portion or all of the processing steps of embodiments of the invention in response to the processors 820 executing one or more sequences of one or more instructions contained in a memory, such as the system memory 830. Such instructions may be read into the system memory 830 from another computer readable medium, such as a magnetic hard disk 841 or a removable media drive 842. The magnetic hard disk 841 may contain one or more datastores and data files used by embodiments of the present invention. Datastore contents and data files may be encrypted to improve security. The processors 820 may also be employed in a multi-processing arrangement to execute the one or more sequences of instructions contained in system memory 830. In alternative embodiments, hard-wired circuitry may be used in place of or in combination with software instructions. Thus, embodiments are not limited to any specific combination of hardware circuitry and software.

As stated above, the computer system 810 may include at least one computer readable medium or memory for holding instructions programmed according to embodiments of the invention and for containing data structures, tables, records, or other data described herein. The term “computer readable medium” as used herein refers to any medium that participates in providing instructions to the processors 820 for execution. A computer readable medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 841 or removable media drive 842. Non-limiting examples of volatile media include dynamic memory, such as system memory 830. Non-limiting examples of transmission media include coaxial cables, copper wire, and fiber optics, including the wires that make up the system bus 821. Transmission media may also take the form of acoustic or light waves, such as those generated during radio wave and infrared data communications.

The computing environment 800 may further include the computer system 810 operating in a networked environment using logical connections to one or more remote computers, such as remote computing device 880. Remote computing device 880 may be a personal computer (laptop or desktop), a mobile device, a server, a router, a network PC, a peer device, or other common network node, and typically includes many or all of the elements described above relative to computer system 810. When used in a networking environment, computer system 810 may include modem 872 for establishing communications over a network 871, such as the Internet. Modem 872 may be connected to system bus 821 via user network interface 870, or via another appropriate mechanism.

Network 871 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 810 and other computers (e.g., remote computing device 880). The network 871 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite, or any other wireless connection methodology generally known in the art. Additionally, several networks may work alone or in communication with each other to facilitate communication in the network 871.

An executable application, as used herein, comprises code or machine-readable instructions for conditioning the processor to implement predetermined functions, such as those of an operating system, a context data acquisition system or other information processing system, for example, in response to user command or input. An executable procedure is a segment of code or machine-readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters.

A graphical user interface (GUI), as used herein, comprises one or more display images, generated by a display processor and enabling user interaction with a processor or other device and associated data acquisition and processing functions. The GUI also includes an executable procedure or executable application. The executable procedure or executable application conditions the display processor to generate signals representing the GUI display images. These signals are supplied to a display device which displays the image for viewing by the user. The processor, under control of an executable procedure or executable application, manipulates the GUI display images in response to signals received from the input devices. In this way, the user may interact with the display image using the input devices, enabling user interaction with the processor or other device.

The functions and process steps herein may be performed automatically or wholly or partially in response to user command. An activity (including a step) performed automatically is performed in response to one or more executable instructions or device operation without user direct initiation of the activity.

The system and processes of the figures are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. As described herein, the various systems, subsystems, agents, managers, and processes can be implemented using hardware components, software components, and/or combinations thereof. No claim element herein is to be construed under the provisions of 35 U.S.C. 112, sixth paragraph, unless the element is expressly recited using the phrase “means for.”

What is claimed is:

1. A computer-implemented method for a digital companion, the method comprising:
in a computer processor, receiving information representative of human knowledge;
converting the received information into a computer-readable form including at least one task-based process to be performed;
constructing a digital twin of a scene for performing the task-based process;
receiving environmental information from a real-world scene for performing the task-based process;
evaluating the received environmental information to detect an error in the performance of the task-based process; and
providing guidance to a user based on the detected error.

2. The computer-implemented method of claim 1, further comprising:
converting the received information representative of human knowledge into a knowledge graph.

3. The computer-implemented method of claim 1, further comprising:
constructing a process model representative of execution of the task-based process;
constructing a scene model representative of the real-world scene for performing the task-based process; and
constructing a user model representative of a worker performing tasks in the task-based process.

4. The computer-implemented method of claim 3, wherein the scene model is a digital twin of the real-world scene for performing the task-based process.

5. The computer-implemented method of claim 4, further comprising:
updating the digital twin of the real-world scene periodically based on the received environmental information.

6. The computer-implemented method of claim 3, wherein the environmental information from the real-world scene comprises data generated from one or more sensors located in the real-world scene.

7. The computer-implemented method of claim 1, further comprising:
providing the guidance to the user in a head-mounted display using augmented reality.

8. The computer-implemented method of claim 1, further comprising:
providing the guidance to the user by communicating information to the user.

9. The computer-implemented method of claim 1, further comprising:
receiving information regarding the user; and
customizing the guidance provided to the user based on the user information.

10. The computer-implemented method of claim 9, wherein the information regarding the user is obtained from a login of the user to the system.

11. The computer-implemented method of claim 9, wherein the information regarding the user is obtained from a physiological sensor associated with the user.

12. The computer-implemented method of claim 1, further comprising:
storing in a knowledge graph, each step in the task-based process; and
linking to each step and at least one entity required to execute the step.

13. The computer-implemented method of claim 12, further comprising:
for each step, storing information relating to pre-dependencies for performing the task.

14. The computer-implemented method of claim 1, wherein constructing the digital twin of the scene comprises:
receiving a captured image from the scene; and
classifying entity objects in the captured image.

15. The computer-implemented method of claim 14, wherein each classified entity object is associated with a unique identifier identifying the entity object based on a semantic model of the system.

16. The computer-implemented method of claim 14, wherein each entity object is classified using a neural network model.

17. The computer-implemented method of claim 1 14 further comprising:
analyzing the digital twin to mark each object as to whether it is expected in the scene.

18. A system for providing a digital companion comprising:
a computer processor in communication with a non-transitory memory, the non-transitory memory storing instructions that when executed by the computer processor cause the processor to:
instantiate a knowledge transfer module for receiving information representative of human knowledge and convert the information into a machine-readable form;
create a knowledge base comprising a process model representative of a step-based process performed using the human knowledge;
create a perception grounding module that identifies entities in a physical world and builds a digital twin of the physical world;
create a perception attention module for evaluating the digital twin of the physical world to detect an error in execution of the step-based process; and
create a user engagement module for communication of a detected error to a user operating in the physical world.

19. The system of claim 18, the knowledge base comprising:
a process model representative of the step-based process;
a scene model representative of the physical world; and
a user model representative of the user.

20. The system of claim 18, further comprising:
a communicating device to communicate the detected error to the user.
